(19) United States
(12) Patent Application Publication
(10) Pub. No.: US 2026/0104476 A1
(43) Pub. Date: Apr. 16, 2026

(54) CALIBRATION DEVICE FOR MAGNETIC FIELD SENSOR

(71) Applicants: Sercomm Corporation, Taipei City (TW); Sernet (Suzhou) Technologies Corporation, Jiangsu (CN)

(72) Inventor: HAIXING ZHONG, Jiangsu (CN)

(21) Appl. No.: 19/294,701

(22) Filed: Aug. 8, 2025

(30) Foreign Application Priority Data
Oct. 14, 2024 (CN) 202411432913.0

(51) Int. Cl. G01R 33/00

(52) U.S. Cl. CPC G01R 33/0035

(57) ABSTRACT

A calibration device comprises a base, a rotating plate disposed on the base, a first and second support arms disposed on two sides of the rotating plate, a frame pivotally coupled to one end of each of the first and second support arms, and a loading trey pivotally coupled to two sides of the frame. The loading trey includes clamps for mounting the magnetic field sensor. When multiple external forces are applied, the rotating plate is configured to horizontally rotate along a center of the first surface of the base as a Z-axis, the frame is configured to pivot along a line between one end of each of the first and second support arms as an X-axis, and the loading trey is configured to pivot along a line between centers of two sides of the frame as a Y-axis, to calibrate magnetic field sensor.

This application claims the benefit of People’s Republic of China application No. CN202411432913.0, filed October 14, 2024, the disclosure of which is incorporated by reference herein in its entirety.

### TECHNICAL FIELD

The disclosure relates in general to calibration device for magnetic field sensor, and more particularly, to techniques of calibration device for calibrating magnetic field sensor by three-axis rotation.

### BACKGROUND

Magnetic field sensors can also be referred to as magnetic force sensors or magnetic field sensing devices (hereinafter referred to as M sensors). M sensors detect changes in the magnetic field in the surrounding environment through magnetic sensitive elements (such as Hall elements, magnetoresistive elements, etc.) inside the M sensors. When a change in the magnetic field is detected, the M sensor can convert this physical signal into an electronic signal (such as voltage, current or digital signal) so that these signals can be processed and analyzed. Typically, the M sensor is combined with an accelerometer (such as G sensor) or a gyroscope to measure the direction of the Earth's magnetic field to achieve device orientation. Therefore, there is a need for techniques of calibrating the M sensor for accurately measuring and reporting changes in the magnetic field.

### SUMMARY

By placing an M sensor on a loading trey (located in the middle of the calibration device), the calibration device for a magnetic field sensor provided by the present disclosure rotates the M sensor in three axes, so that the normal direction of the M sensor points to all eight quadrants of the three-dimensional space to meet the calibration requirements of the M sensor.

The first aspect of the present disclosure features a calibration device for a magnetic field sensor. The calibration device includes a base including a first surface. The calibration device also includes a rotating plate disposed on the first surface of the base and configured to rotate in a horizontal direction with a center of the first surface of the base as a Z-axis when subjected to an external force. The calibration device also includes a first support arm including a first end disposed on a first side of the rotating plate. The calibration device also includes a second support arm including a first end disposed on a second side of the rotating plate. The calibration device also includes a frame including a first side, a second side, a third side and a fourth side, wherein the first side and the third side of the frame are perpendicular to the second side and the third side of the frame. A center of the first side and a center of the third side of the frame are respectively pivotally connected to a second end, opposite to the first end, of the first support arm, and a second end, opposite to the first end, of the second support arm. The frame is configured to pivot along a line between the second end of the first support arm and the second end of the second support arm as an X-axis when subjected to an external force. The calibration device also includes a loading trey coupled to a center of the second side and a center of the third side of the frame, and the loading trey is configured to pivot along a line between the center of the second side and the center of the fourth side of the frame as a Y axis when subjected to an external force. The loading trey includes clamps for mounting the magnetic field sensor.

The details of one or more disclosed implementations are set forth in the accompanying drawings and the description below. Other features, aspects, and advantages will become apparent from the description, the drawings and the claims.

### BRIEF DESCRIPTION OF THE DRAWINGS

FIG. 1 is a diagram illustrating a calibration requirement of M sensor, according to implementations of the present disclosure.

FIG. 2A is a diagram illustrating a stereo view of an example calibration device with a loading trey mounting an M sensor, according to implementations of the present disclosure.

FIG. 2B is a diagram illustrating a stereo view of the example calibration device with the loading trey pivoting and mounting the M sensor, according to implementations of the present disclosure.

FIG. 3A is a diagram illustrating a partial enlarged stereo view of the example calibration device with the loading trey mounting the M sensor, according to implementations of the present disclosure.

FIG. 3B is a diagram illustrating a partial enlarged stereo view of the example calibration device with the loading trey mounting another M sensor, according to implementations of the present disclosure.

FIGS. 4A and 4B are diagrams respectively illustrating side views of the example calibration device along the Y-axis, according to implementations of the present disclosure.

FIG. 4C is a diagram illustrating a side view of the example calibration device along the X-axis, according to implementations of the present disclosure.

FIG. 5A is a diagram illustrating a stereo view of the example calibration device with a pedal rotating mechanism according to implementations of the present disclosure.

FIG. 5B is a diagram illustrating a partial enlarged stereo view of the pedal rotating mechanism of the example calibration device, according to implementations of the present disclosure.

FIGS. 6A and 6B are diagrams respectively illustrating data tables of the example calibration device for calibrating the M sensor, according to implementations of the present disclosure.

In the following detailed description, for purposes of explanation, numerous specific details are set forth in order to provide a thorough understanding of the disclosed implementations. It will be apparent, however, that one or more implementations may be practiced without these specific details. In other instances, well-known structures and devices are schematically shown in order to simplify the drawing.

### DETAILED DESCRIPTION

These illustrative examples are given to introduce the reader to the general subject matter discussed here and are not intended to limit the scope of the disclosed concepts. The following sections describe various additional features and examples with reference to the drawings in which like numerals indicate like elements, and directional descriptions are used to describe the illustrative implementations but, like the illustrative implementations, should not be used to limit the present disclosure. The elements included in the illustrations herein may not be drawn to scale.

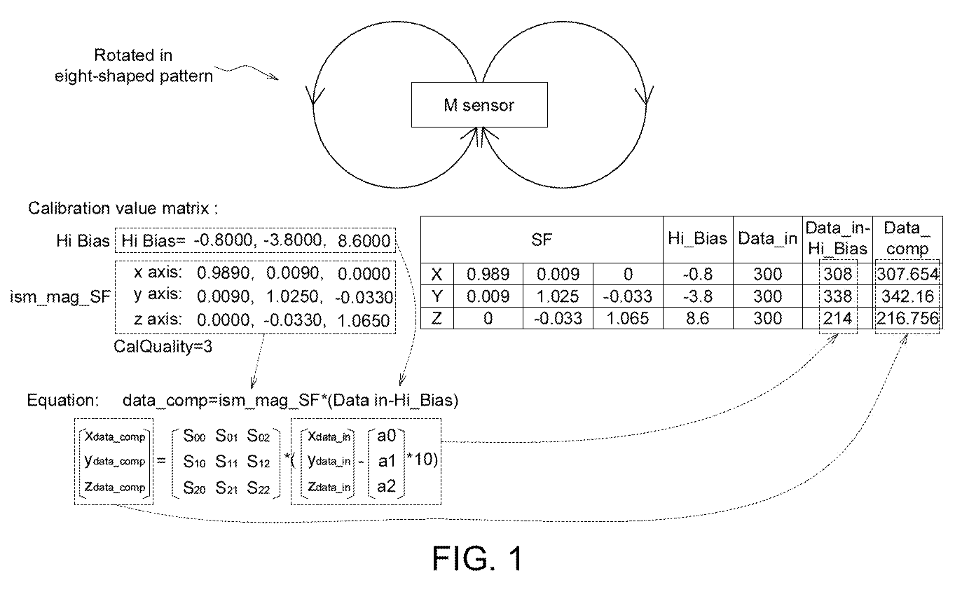

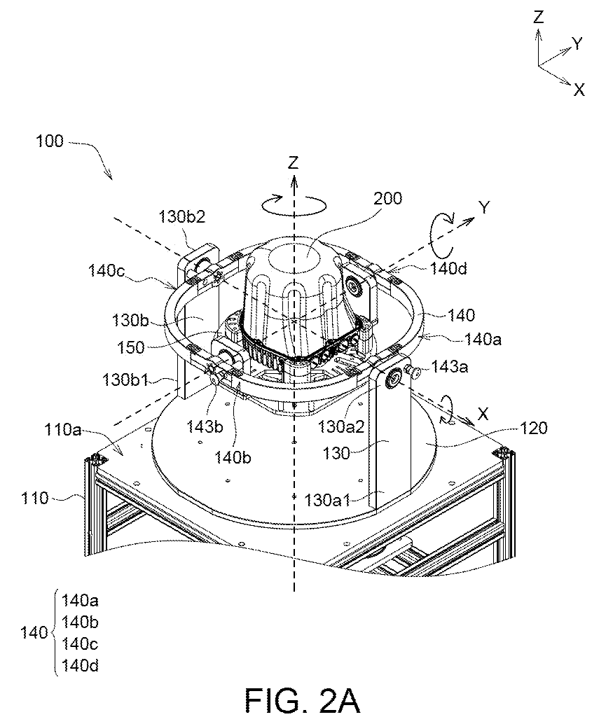

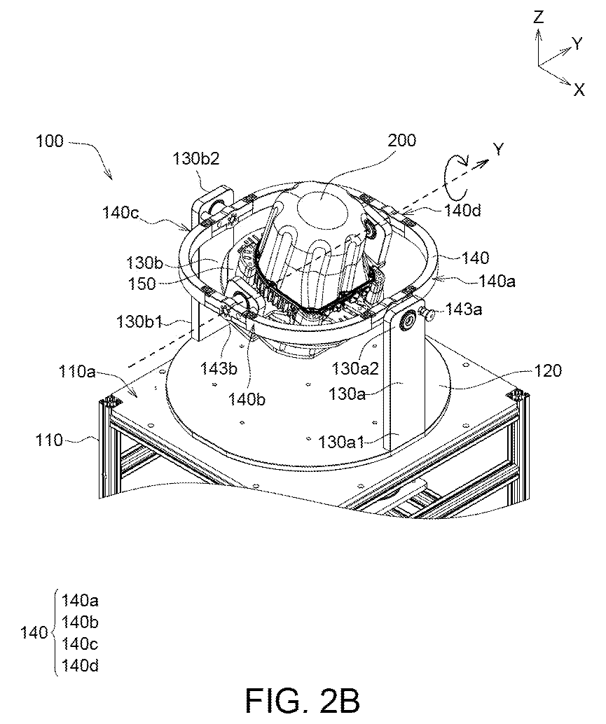

FIG. 1 is a diagram illustrating a calibration requirement of M sensor, according to implementations of the present disclosure. Calibration of the magnetic field sensor (M sensor) is crucial to ensure that the M sensor can accurately measure and report changes in the magnetic field. Therefore, during calibration, the M sensor must be rotated in an eight-shaped pattern in mid-air, as shown in the upper portion of FIG. 1, with its normal directed as closely as possible to all eight quadrants of space. This inputs calibration commands, which in turn cause it to output a 3X4 matrix of calibration values generated within the chip (as shown in the equation at the lower portion of FIG. 1), as shown in the calibration value matrix at the lower portion of FIG. 1. Wherein, Hi_Bias represents the performance of the M sensor under different bias voltages, Data_in represents the actual measured value of the chip, and data_comp represents the theoretical value of the actual measured value after compensation by the calibration value. To achieve the above objectives, the calibration device provided in the present disclosure can mount the M sensor to a loading trey (located in the center of the calibration device) to enable three-axis rotation of the M sensor. This allows the M sensor normal to point to all eight quadrants of three-dimensional space, thereby meeting the M sensor calibration requirements. The techniques of the calibration device for mounting the M sensor provided by the present disclosure will be detailed described referring to FIGS. 2A to 5B as follows.

FIG. 2A is a diagram illustrating a stereo view of an example calibration device 100 with a loading trey 150 mounting an M sensor 200, and FIG. 2B is a diagram illustrating a stereo view of the example calibration device 100 with the loading trey 150 pivoting, according to implementations of the present disclosure. As shown in FIG. 2A, the calibration device 100 includes a base 110 having a first surface 110a. The calibration device 100 also includes a rotating plate 120 disposed on the first surface 110a of base 110. A normal line to the center of the rotating plate 120 can be used as a Z-axis. When subjected to an external force (e.g., manual rotation or rotation by another mechanism), the rotating plate is configured to rotate horizontally at the center of the first surface 110a of base 110 as the Z-axis.

The calibration device 100 also includes a first support arm 130a and a second support arm 130b. A first end 130a1 of the first support arm 130a and a first end 130b1 of the second support arm 130b are respectively disposed on two opposite sides of the rotating plate 120. The calibration device 100 also includes a frame 140 having a first side 140a, a second side 140b, a third side 140c, and a fourth side 140d. The first side 140a and the third side 140c are perpendicular to the second side 140b and the fourth side 140d. A center of the first side 140a and a center of the third side 140c are pivotally connected to a second end 130a2 of the first support arm 130a, which is opposite to the first end 130a1, and a second end 130b2 of the second support arm 130b, which is opposite to the first end 130b1. The line connecting the second end 130a2 of the first support arm 130a and the second end 130b2 of the second support arm 130b can used as an X-axis. The frame 140 is configured to pivot around the X-axis when subjected to an external force (such as rotated by hand or other mechanism).

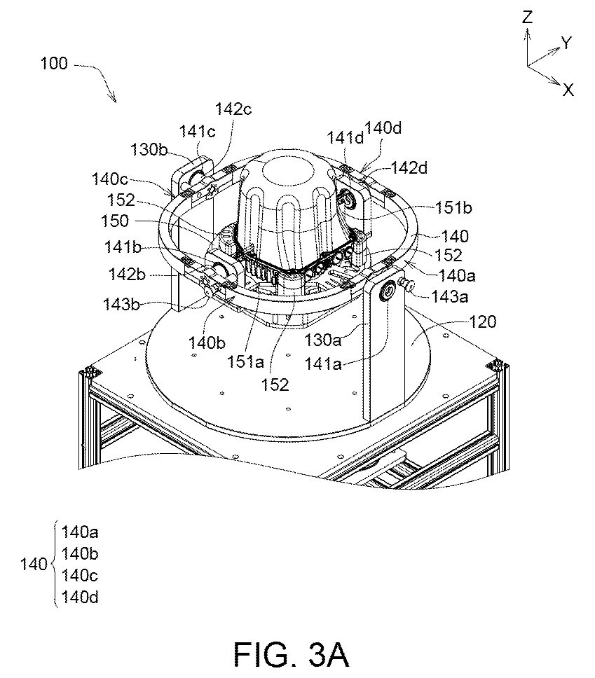

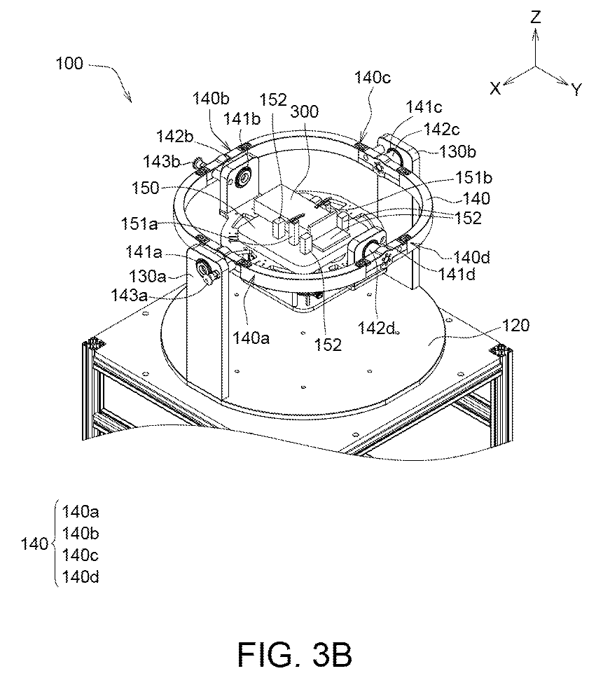

The calibration device 100 also includes a loading trey 150, which is pivotally connected to a center of the second side 140b and a center of the fourth side 140d of the frame 140. The center of the second side 140b and the center of the fourth side 140d of the frame 140 can be regarded as a Y axis. The loading trey 150 is configured to pivot around the Y-axis when subjected to external force (such as manual force, the weight of the M sensor 200 itself, or rotated by other mechanisms). As shown in FIG. 2B, the loading trey 150 mounting the M sensor 200 can pivot around the Y-axis. As discussed above, the frame 140 can pivot around the X-axis, and the rotating plate 120 can drive the first support arm 130a, the second support arm 130b, the frame 140, and the loading trey 150 mounted thereon to rotate around the Z-axis. This enables the M sensor 200 to rotate along three axes, ensuring that the normal direction of the M sensor 200 points to all eight quadrants of three-dimensional space, thus meeting calibration requirements of the M sensor 200. The design details of the calibration device capable of mounting the M sensor provided by the present disclosure will be detailed described referring to FIGS. 3A and 3B as follows.

FIG. 3A is a diagram illustrating a partial enlarged stereo view of the example calibration device 100 with the loading trey 150 mounting the M sensor 200, according to implementations of the present disclosure. The first side 140a of the frame 140 includes a first protruding shaft 142a pivotally connected to a first bearing 141a at the second end 130a2 of the first support arm 130a. Correspondingly, the third side 140c of the frame 140 includes a third protruding shaft 142c pivotally connected to a third bearing 141c at the second end 130b2 of the second support arm 130b. Thus, the frame 140 can respectively pivotally connect to and pivot along the first bearing 141a of the first support arm 130a and the third bearing 141c of the second support arm 130b (around the X-axis) via the first protruding shaft 142a and the third protruding shaft 142c.

The loading trey 150 includes a second bearing 141b and a fourth bearing 141d, which are pivotally connected to a second protruding shaft 142b disposed on the center of the second side 140b and a fourth protruding shaft 142d disposed on the center of the fourth side 140d of the frame 140, respectively. Thus, the loading trey 150 can pivot relative to the frame 140 (around the Y-axis) due to the pivotal connection between the second bearing 141b and the fourth bearing 141d, and the second protruding shaft 142b and the fourth protruding shaft 142d of the frame 140. The first, second, third, and fourth bearings can be made of ceramic to reduce friction during pivoting.

A Y-axis pull pin 143b, adjacent to the second protruding shaft 142b, is disposed between the loading trey 150 and the second side 140b of the frame 140. Similarly, an X-axis pull pin 143a, adjacent to the first bearing 141a, is disposed between the first side 140a of the frame 140 and the second end 130a2 of the first support arm 130a. The Y-axis pull pin 143b can selectively mount the loading trey 150 and the frame 140, for example, by passing through corresponding openings in the loading trey 150 and the frame 140 to prevent the loading trey 150 from pivoting relative to the frame 140 when pivoting is not required. Similarly, the X-axis pull pin 143a can selectively mount the frame 140 and the first support arm 130a, for example, by passing through corresponding openings in the frame 140 and the first support arm 130a to prevent the frame 140 from pivoting relative to the first support arm 130a and the second support arm 130b when pivoting is not required. In some implementations, an X-axis pull pin can also be disposed between the frame 140 and the second support arm 130b to mount the frame 140 and the second support arm 130b.

In some implementations, to prevent wireless signals from interfering with signal of the M sensor, calibration signals must be transmitted via wired transmission. Regarding that, the loading trey 150 may include a connector (not shown). When the M sensor 200 is mounted on the loading trey 150, the M sensor 200 can be communicatively connected to the connector. A Y-axis conductive ring (not shown) may be disposed on the second bearing 141b between the loading trey 150 and the second side 140b of the frame 140. Similarly, an X-axis conductive ring (not shown) may be disposed on the first bearing 141a between the first side 140a of the frame 140 and the second end 130a2 of the first support arm 130a. The connector, the Y-axis conductive ring, and the X-axis conductive ring are electrically connected. Therefore, when the M sensor 200 is mounted on the loading trey 150 and communicatively connected to the connector, the X-axis conductive ring can be communicatively connected to an external device. This allows the M sensor 200 to communicate with the external device via wired communication when the loading trey 150 pivots along the Y-axis and the frame 140 pivots along the X-axis, and signal communication is not interrupted during the rotation calibration process.

The loading trey 150 may also include a clamp 151a and a clamp 151b, which may clamp the M sensor 200 on the loading trey 150. The loading trey 150 may also include multiple stoppers 152, which are used to fix the M sensor 200 on the loading trey 150. The base 110, the rotating plate 120, the first support arm 130a, the second support arm 130b, the frame 140, the loading trey 150, the clamp 151a and the clamp 151b may be made of aluminum, and the stoppers may be made of anti-magnetic plastic steel, such as Polyoxymethylene (POM) to prevent the magnetic field from being disturbed during the calibration process and causing the M sensor 200 to deviate.

FIG. 3B is a diagram illustrating a partial enlarged stereo view of the example calibration device 100 with the loading trey 150 mounting another M sensor 300, according to implementations of the present disclosure. As shown in FIG. 3B, the loading trey 150 can be used to mount M sensors 300, one of various types of M sensors, by replacing the aforementioned clamps and blocks. Similarly, the clamps 151a and 151b on the loading trey 150 can be used to clamp the M sensor 300 on the loading trey 150, and the multiple blocks 152 on the loading trey 150 can be used to fix the M sensor 300 on the loading trey 150.

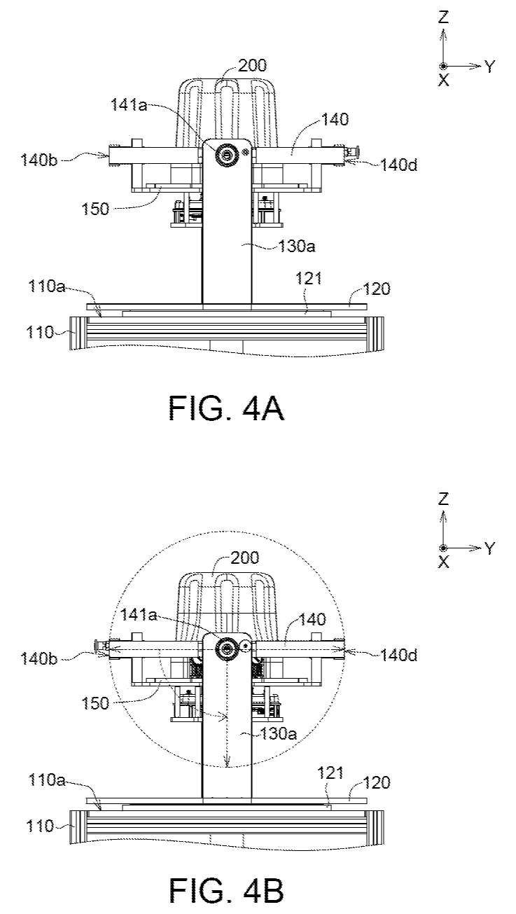

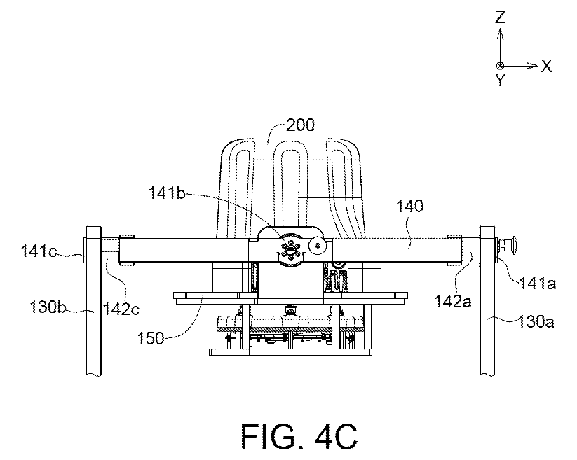

FIGS. 4A and 4B are diagrams respectively illustrating side views of the example calibration device 100 along the Y-axis, according to implementations of the present disclosure. As shown in FIG. 4A and FIG. 4B, the rotating plate 120 can be coupled to the first surface 110a of the base 110 via a universal turntable 121, allowing the rotating plate 120 to rotate horizontally relative to the first surface 110a of the base 110. The universal turntable 121 has a thickness of at least 30 mm, so that the distance between the rotating plate 120 and the first surface 110a of the base 110 is greater than 30 mm to avoid mutual interference. Referring to FIG. 4B , a half of the distance between the center of the second side 140b and the center of the fourth side 140d of the frame 140, that is, the distance from the geometric center of the frame 140 to the center of the second side 140b and the center of the fourth side 140d, is at least 40 mm greater than the distance between the first bearing 141a and the third bearing (not shown), and the rotating plate 120, so as to avoid interference between the frame 140 and the rotating plate 120 when pivoting.

FIG. 4C is a diagram illustrating a side view of the example calibration device 100 along the X-axis, according to implementations of the present disclosure. The distance between the first bearing 141a and the center of the first side 140a of the frame 140 and the distance between the third bearing 141c and the center of the third side 140c of the frame 140 are at least 30 mm to prevent the frame 140 from interfering with the first support arm 130a and the second support arm 130b when pivoting.

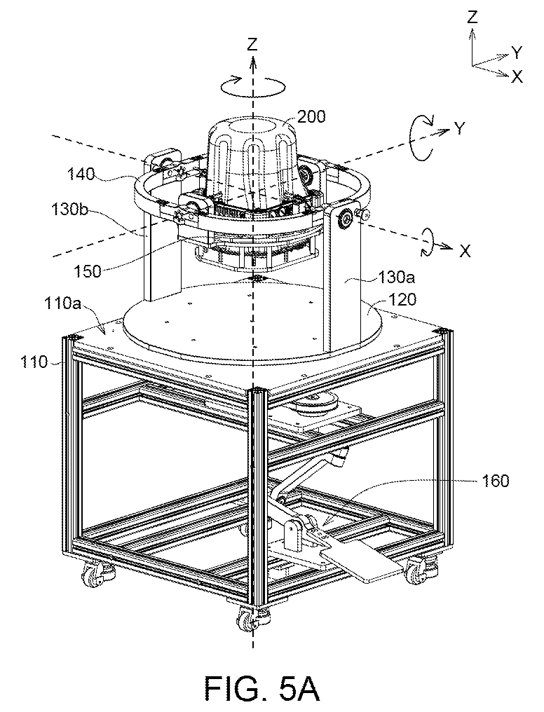

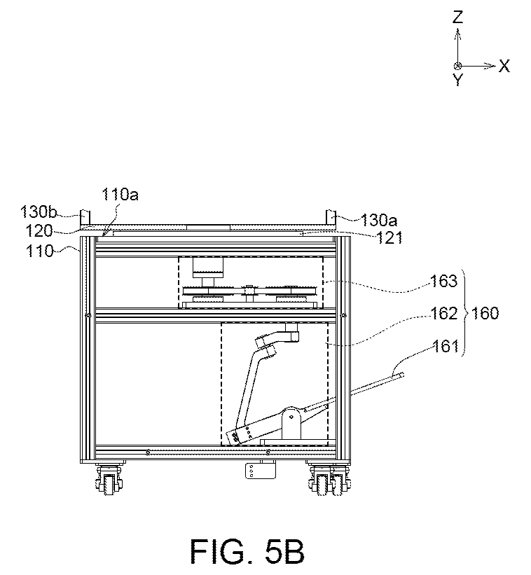

FIG. 5A is a diagram illustrating a stereo view of the example calibration device 100 with a pedal rotating mechanism 160, and FIG. 5B is a diagram illustrating a partial enlarged stereo view of the pedal rotating mechanism 160 of the example calibration device 100, according to implementations of the present disclosure. Referring to both FIG. 5A and FIG. 5B, in some implementations, the base 110 may include the pedal rotation mechanism 160 on the side opposite to the first surface 110a to provide an external force to rotate the rotating plate 120 (or the universal turntable 121) around the Z-axis. The pedal rotation mechanism 160 may include a foot pedal 161, a connecting rod assembly 162, and a transmission assembly 163. The two ends of the connecting rod assembly 162 are respectively coupled to the foot pedal 161 and the transmission assembly 163, and the transmission assembly 163 is coupled to the universal turntable 121. When the foot pedal 161 is subjected to external force (such as an operator stepping on the foot pedal), the pedal rotation mechanism 160 drives the connecting rod assembly 162 and the transmission assembly 163 to drive the universal turntable 121 and the rotating plate120 to rotate in the horizontal direction at the center of the first surface 110a of the base 110 as the Z-axis. The transmission assembly 163 may include multiple gears coupled to each other and capable of rotating the axis of the universal turntable 121.

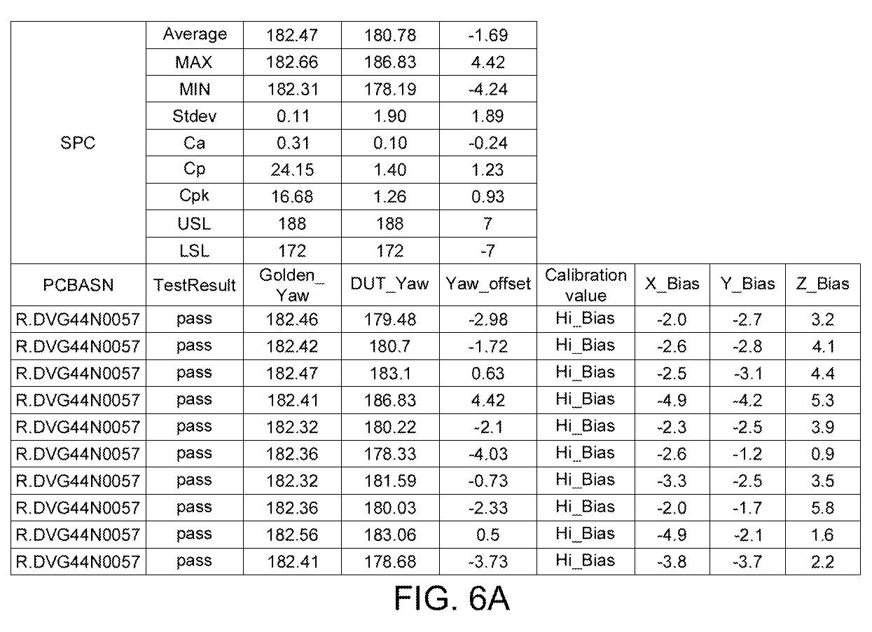

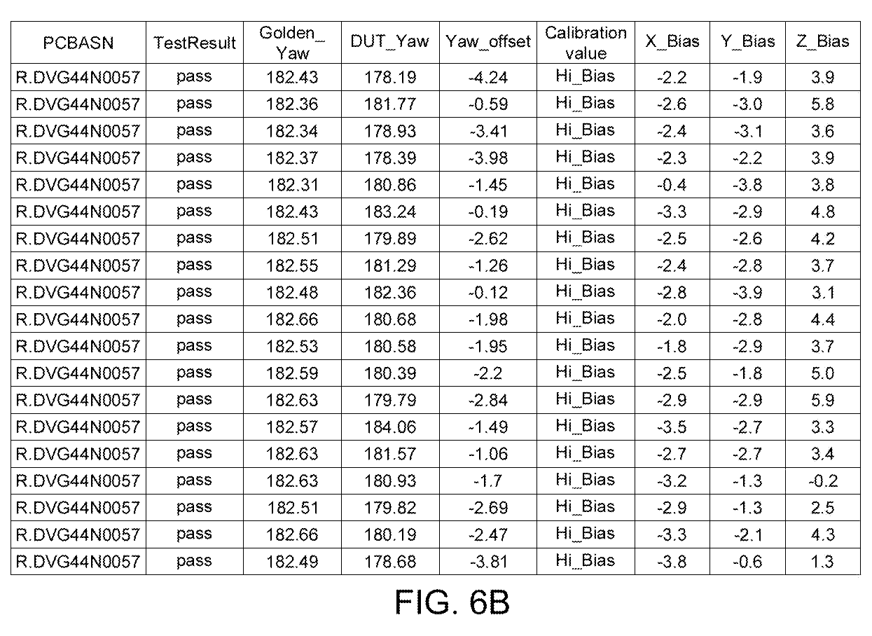

FIGS. 6A and 6B are diagrams respectively illustrating data tables of the example calibration device for calibrating the M sensor, according to implementations of the present disclosure. In the data tables of FIG. 6A and FIG. 6B, Golden_Yaw represents the sampled yaw angle measurement value, DUT_Yaw represents the actual yaw angle value measured after calibration, and Yaw_offset represents the difference between the sampled value and the value, which needs to be within the positive and negative values to meet the calibration requirements. The CPK in the table represents the degree to which the performance of the test process meets the quality standard requirements (specification range, etc.) of the M sensor, and the actual operating ability of the test program under a controlled state (stable state) for a certain period of time. The calculation of the CPK in the table is to confirm whether the measured value is in the middle value of the specification (SPEC). As shown in the table of FIG. 6A and FIG. 6B, the M sensor calibration and certification (Verify) data shows that the CPK averages about 1.1, and the misjudgment rate is about 3.3% (standard <5%), which meets the calibration requirements of the M sensor.

According to implementations above, the techniques of the calibration device provided by the present disclosure enables the M Sensor mounted on the loading trey of the calibration device to rotate simultaneously along three axes (X/Y/Z-axes) to achieve the effect of pointing to the eight quadrants of the three-dimensional space. Additionally, the combination of aluminum, ceramic, POM and other anti-magnetic materials can prevent magnetic field interference. Furthermore, a conductive ring is provided between the loading trey, frame and support arm, and forms a loop structure electrically connected with the connector on the loading trey, so that the signal communication between the M sensor and external devices is not interrupted during the three-axis rotation process. The techniques of calibration device provided by the present disclosure are applicable to M-sensor calibration for various communications products, which offers advantages such as flexibility, ease of operation, compact size, and high efficiency, facilitating calibration of products equipped with M-sensors. Furthermore, by replacing components on the loading trey, the calibration device can be used with products of varying form factors.

While this document may describe many specifics, these should not be construed as limitations on the scope of an invention that is claimed or of what may be claimed, but rather as descriptions of features specific to particular implementations. Certain features that are described in this document in the context of separate implementations can also be implemented in combination in a single embodiment. Conversely, various features that are described in the context of a single embodiment can also be implemented in a plurality of implementations separately or in any suitable sub-combination. Moreover, although features may be described above as acting in certain combinations and even initially claimed as such, one or more features from a claimed combination in some cases can be excised from the combination, and the claimed combination may be directed to a sub-combination or a variation of a sub-combination. Similarly, while operations are depicted in the drawings in a particular order, this should not be understood as requiring that such operations be performed in the particular order shown or in sequential order, or that all illustrated operations be performed, to achieve desirable results.

Only a few examples and implementations are disclosed. Variations, modifications, and enhancements to the described examples and implementations and other implementations can be made according to what is disclosed.

What is claimed is:

1. A calibration device for a magnetic field sensor, comprising:
a base, including a first surface;
a rotating plate disposed on the first surface of the base and configured to rotate in a horizontal direction with a center of the first surface of the base as a Z-axis when subjected to an external force;
a first support arm including a first end, the first end disposed on a first side of the rotating plate;
a second support arm including a first end, the first end disposed on a second side of the rotating plate;
a frame including a first side, a second side, a third side and a fourth side, wherein the first side and the third side of the frame are perpendicular to the second side and the third side of the frame, wherein a center of the first side and a center of the third side of the frame are respectively pivotally connected to a second end, opposite to the first end, of the first support arm, and a second end, opposite to the first end, of the second support arm, and the frame is configured to pivot along a line between the second end of the first support arm and the second end of the second support arm as an X-axis when subjected to an external force; and
a loading trey, coupled to a center of the second side and a center of the third side of the frame, and the loading trey is configured to pivot along a line between the center of the second side and the center of the fourth side of the frame as a Y axis when subjected to an external force,
wherein the loading trey includes clamps for mounting the magnetic field sensor.

2. The calibration device of claim 1, wherein the rotating plate is coupled to the first surface of the base via a universal turntable,
wherein the first side of the frame includes a first protruding shaft pivotally connected to a first bearing at the second end of the first support arm,
wherein the third side of the frame includes a third protruding shaft pivotally connected to a third bearing at the second end of the second support arm,
wherein the loading trey includes a second bearing and a fourth bearing, which are respectively pivotally connected to a second protruding shaft disposed on the center of the second side of the frame and a fourth protruding shaft disposed on the center of the fourth side.

3. The calibration device of claim 2, wherein the loading trey includes a connector, the second bearing between the loading trey and the second side of the frame includes a Y-axis conductive ring, and the first bearing between the first side of the frame and the second end of the first support arm includes an X-axis conductive ring,
wherein the connector, the Y-axis conductive ring, and the X-axis conductive ring are electrically connected.

4. The calibration device of claim 3, wherein the connector is communicatively connected to the magnetic field sensor, and the X-axis conductive ring is communicatively connected to an external device, so that when the loading trey pivots on the Y-axis and the frame pivots on the-X axis, the magnetic field sensor communicates with the external device via wire.

5. The calibration device of claim 2, wherein the first bearing, the second bearing, the third bearing and the fourth bearing are made of ceramic material.

6. The calibration device of claim 2, wherein the base includes a pedal rotating mechanism on an opposite side to the first surface,
wherein the pedal rotating mechanism includes a foot pedal, a connecting rod assembly and a transmission assembly,
wherein one end of the connecting rod assembly is coupled to the foot pedal, and the other end of the connecting rod assembly is coupled to the transmission assembly coupled to the universal turntable,
wherein when the foot pedal is subjected to an external force, the pedal rotating mechanism drives the connecting rod assembly and the transmission assembly to drive the universal turntable and the rotating plate to rotate in the horizontal direction with the center of the first surface of the base as the Z-axis.

7. The calibration device of claim 2, wherein a Y-axis pull pin, adjacent to the second protruding shaft, is disposed between the loading trey and the second side of the frame, and an X-axis pull pin, adjacent to the first bearing, is disposed between the first side of the frame and the second end of the first support arm,
Wherein the Y-axis pull pin selectively mounts the loading trey and the frame to prevent the loading trey from pivoting relative to the frame, and the X-axis pull pin selectively mounts the frame and the first support arm to prevent the frame from pivoting relative to the first support arm and the second support arm.

8. The calibration device of claim 2, wherein a half of a distance between the center of the second side and the center of the fourth side of the frame is at least 40 mm greater than a distance between the first bearing and the third bearing, and the rotating plate,
wherein a thickness of the universal turntable is at least 30 mm, so that a distance between the rotating plate and the first surface of the base is greater than 30 mm,
wherein a distance between the first bearing and the center of the first side of the frame and a distance between the third bearing and the center of the third side of the frame are at least 30 mm.

9. The calibration device of claim 1, wherein the base, the rotating plate, the first support arm, the second support arm, the frame, the loading trey and the clamps are made of aluminum.

10. The calibration device of claim 1, wherein the loading trey further includes a plurality of blocks for fixing the magnetic field sensor, and the blocks are made of POM (Polyoxymethylene) as anti-magnetic plastic steel.
